(19) United States
(12) Patent Application Publication
(10) Pub. No.: US 2023/0369161 A1
(43) Pub. Date: Nov. 16, 2023

(54) Semiconductor Device and Method for Manufacturing the Same

(71) Applicant: Nippon Telegraph and Telephone Corporation, Tokyo (JP)

(72) Inventors: Yusuke Araki, Musashino-shi, Tokyo (JP); Kei Watanabe, Musashino-shi, Tokyo (JP); Yuta Shiratori, Musashino-shi, Tokyo (JP)

(21) Appl. No.: 18/246,619

(22) PCT Filed: Sep. 28, 2020
(86) PCT No.: PCT/JP2020/036564

§ 371 Date: Mar. 24, 2023

(51) Int. Cl. H01L 23/367; H01L 23/00; H01L 25/065

(52) U.S. Cl. CPC H01L 23/3675; H01L 24/24; H01L 24/96; H01L 24/32; H01L 24/73; H01L 25/0655; H01L 2224/24137; H01L 2224/96; H01L 2924/351; H01L 2224/32225; H01L 2224/73267

(57) ABSTRACT

A semiconductor device includes a wiring layer, and a first semiconductor chip and a second semiconductor chip disposed on the wiring layer. In addition, the semiconductor device includes a heat sink disposed on a back surface side of the first semiconductor chip and a back surface side of the second semiconductor chip. The heat sink includes a material having a thermal conductivity greater than thermal conductivities of the first semiconductor chip and the second semiconductor chip, and a reinforcing rib is formed on the heat sink.

### TECHNICAL FIELD

The present invention relates to a semiconductor device and a method for manufacturing the same.

### BACKGROUND ART

In recent years, further improvement has been required in performance of mobile terminals including smartphones. For this reason, different materials integration, integration scale improvement, and high-frequency signal transmission are required for semiconductor packages constituting a mobile terminal. In addition, since the semiconductor packages are for mobile applications, thinning of the semiconductor packages is also required. As a technology for achieving them, a wafer level package (WLP) have attracted attention.

In the WLP, since semiconductor chips of various materials and shapes are sealed with a molding resin, integration of different materials is possible. In addition, with improvement of patterning accuracy of exposure devices and accuracy of the chip transfer machines, wiring can be performed finely and highly accurately between different semiconductor chips, and thus, improvement of integration scale and transmission of high-frequency signals can be achieved. Further, in flip chip mounting that is a conventional semiconductor package mounting technology, a package substrate is required, but in the WLP, the package substrate is not required, and thinning of the semiconductor packages can be achieved.

As a method for manufacturing the WLP, for example, as described in Non Patent Literature 1, there are various manufacturing methods such as a “face-down” method and a “face-up” method. Any manufacturing methods are characterized by batch manufacturing at the wafer level and can reduce the cost per package.

As an example of the method for manufacturing the WLP, a “face-up” method manufacturing method will be described. First, an adhesive layer is formed on a support substrate, and a semiconductor chip is mounted on the adhesive layer using a chip transfer machine. In this mounting, a back surface of the semiconductor chip with respect to a circuit formation surface is brought into contact with the adhesive layer. Subsequently, the semiconductor chip is sealed with a molding resin to form a dummy wafer. Further, the molding resin sealing the semiconductor chip is ground to expose the circuit formation surface of the semiconductor chip. Next, a wiring layer is formed on the exposed circuit formation surface by a known build-up method. Finally, the support substrate and the adhesive layer are peeled off from the dummy wafer, and singulation into individual packages is performed.

As described above, the WLP has various merits. However, the WLP also has problems. One of the problems is heat dissipation due to sealing of the semiconductor chip with the molding resin. The thermal conductivity of the molding resin used for the WLP is typically around 1 W/m·K. This value is smaller than about 170 W/m·K, which is a value of Si as a typical semiconductor chip, and about 400 W/m·K, which is a value of copper as a typical material of a heat dissipation substrate. Heat generated in the semiconductor chip sealed with such a molding resin cannot be diffused, which may lead to a temperature rise of the semiconductor chip.

Against the background of the problem regarding the heat dissipation described above, a technology has been devised for improving heat dissipation characteristics of a WLP structure. As a typical technology, there is a method of attaching a heat dissipation substrate to a semiconductor chip. This will be described with reference to FIG. 4.

In this semiconductor device, two semiconductor chips 302 and 303 are sealed by a molding resin layer 305 on a wiring layer 301. In addition, the semiconductor chip 302 and the semiconductor chip 303 are provided with a heat dissipation substrate 307 with an adhesive layer 306 interposed therebetween. In addition, an integrated circuit 302a of the semiconductor chip 302 and an integrated circuit 303a of the semiconductor chip 303 are electrically connected to each other through wiring 301a formed in the wiring layer 301. In addition, a terminal 301b is disposed below the wiring layer 301, and the wiring layer 301 is connected (mounted) to a printed circuit board (not illustrated) through the terminal 301b.

In the semiconductor device, heat generated in the semiconductor chip 302 and the semiconductor chip 303 is diffused from the heat dissipation substrate 307 to the atmosphere through the adhesive layer 306, so that the heat dissipation of the WLP can be improved.

In addition, there is a semiconductor device for which heat dissipation improvement of the WLP structure is attempted that is disclosed in Non Patent Literature 2. The semiconductor device will be described with reference to FIG. 5. In the semiconductor device, the two semiconductor chips 302 and 303 are sealed by a sealing layer 315 including Cu on the wiring layer 301. The periphery of the semiconductor device is surrounded by a silicon layer 316. Note that the integrated circuit 302a of the semiconductor chip 302 and the integrated circuit 303a of the semiconductor chip 303 are electrically connected to each other through the wiring 301a formed in the wiring layer 301. In addition, a terminal 301b is disposed below the wiring layer 301, and the wiring layer 301 is connected (mounted) to a printed circuit board (not illustrated) through the terminal 301b.

In the semiconductor device, heat generated in the semiconductor chip 302 and the semiconductor chip 303 is diffused from the sealing layer 315 including copper into the atmosphere, so that the heat dissipation of the WLP can be improved. In addition, the outer periphery of the semiconductor device is surrounded by the silicon layer 316, and the thickness of the semiconductor device coincides with the thickness of the silicon layer 316 on the outer periphery, from a manufacturing method to be described later. Thus, thinning of the semiconductor package can be achieved.

### CITATION LIST

### Non Patent Literature

Non Patent Literature 1: J. H. Lau et al., “Recent Advances and Trends in Fan-Out Wafer/Panel-Level Packaging”, Journal of Electronic Packaging, vol. 141, 040801, 2019.
Non Patent Literature 2: J. A. Estrada et al., “Metal-Embedded Chip Assembly Processing for Enhanced RF Circuit Performance”, IEEE Transactions on Microwave Theory and Techniques, vol. 67, no. 9, pp. 3537-3546, 2019.

### SUMMARY OF INVENTION

### Technical Problem

In the semiconductor device described with reference to FIG. 4, two manufacturing methods are conceivable. First, there is a manufacturing method using a plate-shaped heat dissipation substrate as the support substrate. In this manufacturing method, the support substrate is not peeled off after the wiring layer is formed, and singulation into individual packages including the support substrate is performed. However, since the heat dissipation substrate of this manufacturing method requires mechanical strength that can withstand a step of forming the wiring layer, the support substrate serving as the heat dissipation substrate requires a certain thickness. For this reason, in this manufacturing method, thinning of the semiconductor package required for mobile applications is limited.

Secondly, there is a manufacturing method in which after the wiring layer is formed, the support substrate and the adhesive layer are peeled off from the dummy wafer, and a heat sink is attached to each singulated package. In this manufacturing method, mechanical strength is not required for the heat sink. For this reason, the heat sink can be thinned, and it is possible to achieve thinning of the semiconductor package suitable for mobile applications. However, in the second manufacturing method, since the heat sink cannot be provided as batch mounting at the wafer level, the cost per package increases.

As described above, in the semiconductor device described with reference to FIG. 4, it is difficult to achieve both the heat dissipation of the WLP structure and the thinning of the package.

In the semiconductor device described with reference to FIG. 5, the heat dissipation of the WLP can be improved while suppressing the thickness of the semiconductor device by suppressing the thickness of the Si layer on the outer periphery. However, a method for manufacturing this configuration is more costly than the manufacturing method described in Non Patent Literature 1. To describe this, a description will be given of a method for manufacturing the semiconductor device of FIG. 5.

First, the adhesive layer is formed on the support substrate, and the semiconductor chip is mounted on the adhesive layer using a chip transfer machine. At this time, the circuit formation surface of the semiconductor chip is mounted to be in contact with the adhesive layer. Subsequently, a Si interposer wafer including a hole having a size of about each package size is mounted on the support substrate. In this step, the mounted semiconductor chip is placed in the hole of the Si interposer wafer. Thereafter, the hole of the Si interposer wafer is filled with copper by an electroplating method to form the dummy wafer.

Next, the support substrate and the adhesive layer are peeled off from the dummy wafer to expose the circuit formation surface of the semiconductor chip. The wiring layer is formed on the exposed circuit formation surface by the build-up method. Finally, the dummy wafer is singulated into individual packages.

As described above, in the manufacture of the semiconductor device of Non Patent Literature 2, mounting and peeling of the Si interposer wafer and filling of copper are required as compared with the manufacturing method described with reference to Non-Patent Literature 1, so that the step becomes complicated and the manufacturing cost increases. As described above, in the conventional technology, there has been a problem that the WLP structure capable of obtaining high heat dissipation cannot be formed thin in a state where the manufacturing cost is suppressed.

The present invention has been made to solve the above problem, and an object of the present invention is to enable the WLP structure capable of obtaining high heat dissipation to be formed thinner while suppressing manufacturing cost.

### Solution to Problem

A semiconductor device according to the present invention includes: a wiring layer in which wiring is formed; a first semiconductor chip and a second semiconductor chip disposed on the wiring layer and molded with a molding resin layer including a molding resin; a first integrated circuit formed on the first semiconductor chip and connected to the wiring; a second integrated circuit formed on the second semiconductor chip and connected to the wiring; a heat sink that is disposed on a back surface side of the first semiconductor chip and a back surface side of the second semiconductor chip, includes a material having a thermal conductivity greater than thermal conductivities of the first semiconductor chip and the second semiconductor chip, and dissipates heat of the first semiconductor chip and the second semiconductor chip; and a reinforcing rib formed on the heat sink in a region where the first semiconductor chip and the second semiconductor chip are not disposed.

A method for manufacturing a semiconductor device according to the present invention includes: a first step of fixing a back surface of a first semiconductor chip in which a first integrated circuit is formed on a main surface and a back surface of a second semiconductor chip in which a second integrated circuit is formed on a main surface, to a region where a reinforcing rib is not formed, of a heat sink on which the reinforcing rib is formed and that includes a material having a thermal conductivity greater than thermal conductivities of the first semiconductor chip and the second semiconductor chip; a second step of molding the first semiconductor chip and the second semiconductor chip fixed to the heat sink with a molding resin on the heat sink to form a molding resin layer; and a third step of performing formation to a state in which the first semiconductor chip and the second semiconductor chip are disposed on a wiring layer including wiring, the first integrated circuit and the second integrated circuit are connected to the wiring, and the first semiconductor chip and the second semiconductor chip are molded with the molding resin layer on the wiring layer.

### Advantageous Effects of Invention

As described above, according to the present invention, since the heat sink includes the reinforcing rib, it is possible to form a thinner WLP structure capable of obtaining high heat dissipation while the manufacturing cost is suppressed.

### BRIEF DESCRIPTION OF DRAWINGS

FIG. 1A is a cross-sectional view illustrating a configuration of a semiconductor device according to an embodiment of the present invention.

FIG. 1B is a plan view illustrating a partial configuration of the semiconductor device according to the embodiment of the present invention.

FIG. 2A is a cross-sectional view illustrating a state of the semiconductor device in an intermediate step for explaining a method for manufacturing the semiconductor device according to the embodiment of the present invention.

FIG. 2B is a cross-sectional view illustrating a state of the semiconductor device in an intermediate step for explaining a method for manufacturing the semiconductor device according to the embodiment of the present invention.

FIG. 2C is a cross-sectional view illustrating a state of the semiconductor device in an intermediate step for explaining a method for manufacturing the semiconductor device according to the embodiment of the present invention.

FIG. 2D is a cross-sectional view illustrating a state of the semiconductor device in an intermediate step for explaining a method for manufacturing the semiconductor device according to the embodiment of the present invention.

FIG. 3 is a cross-sectional view illustrating a configuration of another semiconductor device according to the embodiment of the present invention.

FIG. 4 is a cross-sectional view illustrating a configuration of a semiconductor device having a WLP structure.

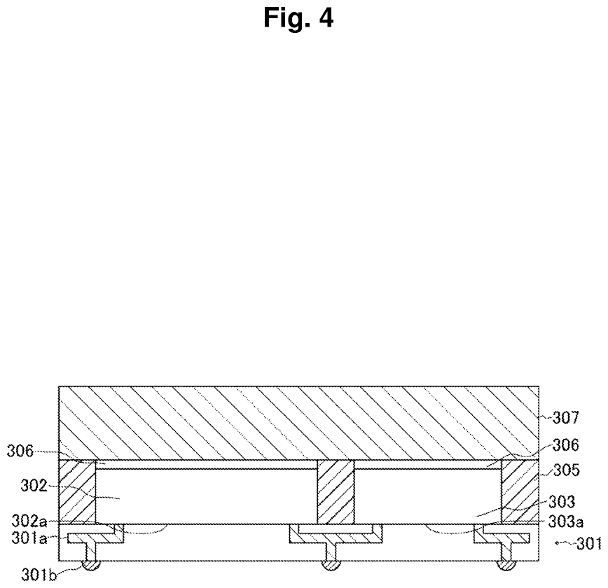

FIG. 5 is a cross-sectional view illustrating a configuration of a semiconductor device having a WLP structure.

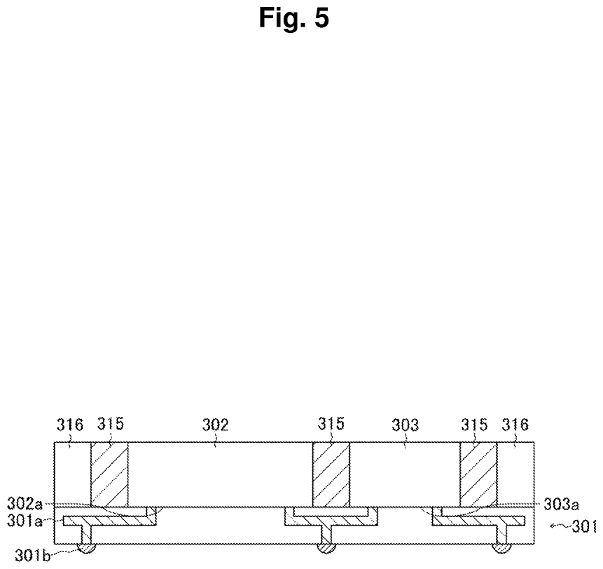

### DESCRIPTION OF EMBODIMENTS

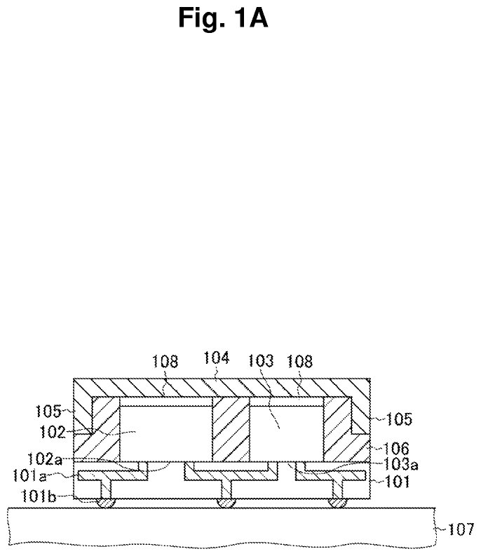

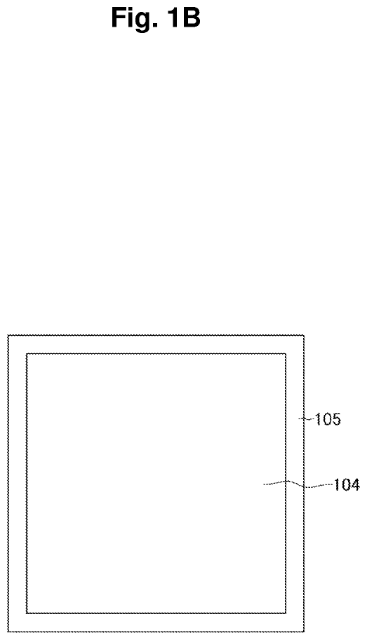

Hereinafter, a semiconductor device according to an embodiment of the present invention will be described with reference to FIGS. 1A and 1B. The semiconductor device includes a wiring layer 101, and a first semiconductor chip 102 and a second semiconductor chip 103 disposed on the wiring layer 101.

The first semiconductor chip 102 and the second semiconductor chip 103 are formed of, for example, a semiconductor such as Si, InP, GaN, or GaAs. The first semiconductor chip 102 and the second semiconductor chip 103 can include different materials. For example, the first semiconductor chip 102 can be manufactured from a compound semiconductor, and the second semiconductor chip 103 can be manufactured from Si.

Wiring 101a including metal is formed in the wiring layer 101. A first integrated circuit 102a electrically connected to the wiring 101a is formed on a main surface of the first semiconductor chip 102 facing the wiring layer 101 side. A second integrated circuit 103a electrically connected to the wiring 101a is formed on a main surface of the second semiconductor chip 103 facing the wiring layer 101 side. The first integrated circuit 102a and the second integrated circuit 103a are connected to each other by the wiring 101a. The first semiconductor chip 102 and the second semiconductor chip 103 are molded by a molding resin layer 106 including a molding resin on the wiring layer 101.

In addition, the semiconductor device includes a heat sink 104 disposed on a back surface side of the first semiconductor chip 102 and a back surface side of the second semiconductor chip 103. The heat sink 104 includes a material having a thermal conductivity greater than thermal conductivities of the first semiconductor chip 102 and the second semiconductor chip 103, and is used to dissipate heat of the first semiconductor chip 102 and the second semiconductor chip 103. The heat sink 104 can include, for example, an insulating material such as silicon carbide, aluminum nitride, beryllium oxide, or diamond.

In this example, the first semiconductor chip 102 and the second semiconductor chip 103 are bonded and fixed to the heat sink 104 using an adhesive layer 108. The adhesive layer 108 can include, for example, solder containing lead and tin as main components. In this case, the first semiconductor chip 102 and the second semiconductor chip 103 are fixed to the heat sink 104 by so-called soldering. In addition, the first semiconductor chip 102 and the second semiconductor chip 103 can be fixed to the heat sink 104 by a known direct bonding technology. In this case, the first semiconductor chip 102 and the second semiconductor chip 103 are fixed in direct contact with the heat sink 104.

Here, in the semiconductor device, a reinforcing rib 105 is formed on the heat sink 104. The reinforcing rib 105 is a columnar structure formed on a surface of the plate-shaped heat sink 104 on the wiring layer 101 side and extending in the planar direction of the heat sink 104. The reinforcing rib 105 can be, for example, a columnar structure having a rectangular cross section. The reinforcing rib 105 is formed on the heat sink 104 in a region where the first semiconductor chip 102 and the second semiconductor chip 103 are not disposed. For example, as illustrated in FIG. 1B, the reinforcing rib 105 can be disposed in a peripheral portion of the heat sink 104 having a rectangular shape in a plan view in a state of surrounding the inside of the heat sink 104. In addition, the reinforcing rib 105 can also be disposed in a lattice shape on a plane of heat sink 104 in a plan view. The heat sink 104 and the reinforcing rib 105 can be integrally formed.

As described above, since the strength of the heat sink 104 can be enhanced by providing the reinforcing rib 105, the plate thickness of the heat sink 104 can be made thinner, and the WLP structure capable of obtaining high heat dissipation can be formed thinner. Note that heat generated in the first semiconductor chip 102 and the second semiconductor chip 103 is diffused from the heat sink 104 into the atmosphere. In a case where the adhesive layer 108 is used, heat generated in the second semiconductor chip 103 is diffused into the atmosphere from the heat sink 104 via the adhesive layer 108. In this configuration, since the molding resin layer 106 is not interposed in a heat dissipation path, heat dissipation can be improved.

Note that, in the semiconductor device (package), a terminal 101b is formed under the wiring layer 101, and the wiring layer 101 is electrically connected (mounted) to a printed circuit board 107 through the terminal 101b. In this example, secondary mounting of the WLP on the printed circuit board 107 by the face-down method is exemplified, but effects of the present invention can also be obtained by another method such as the face-up method of the WLP, or a design in which the secondary mounting is not performed.

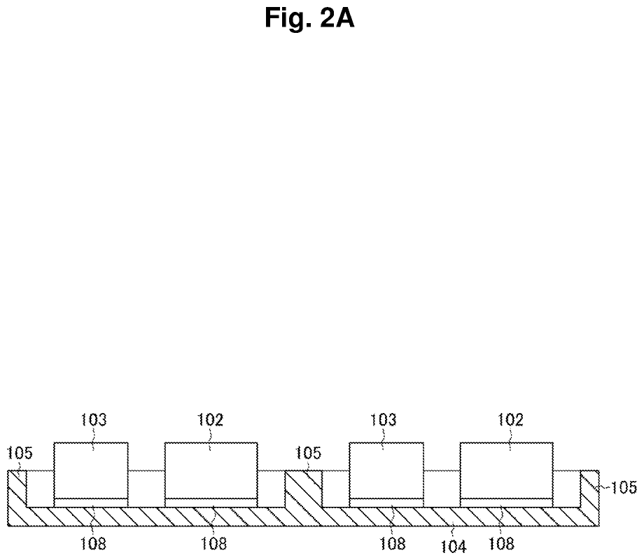

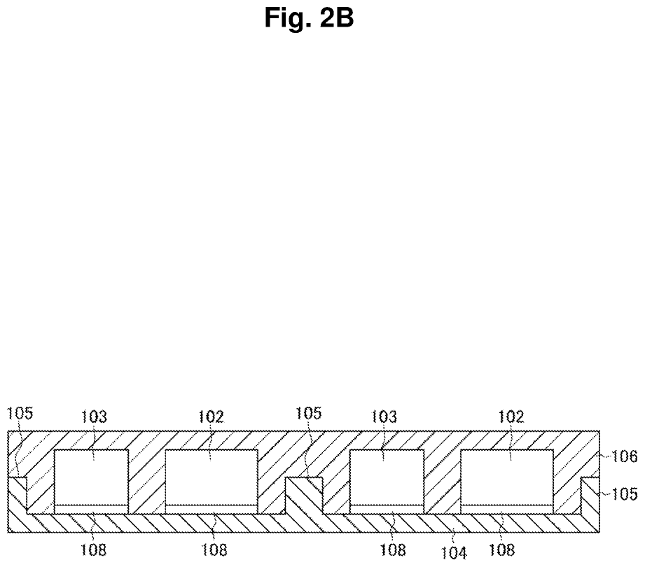

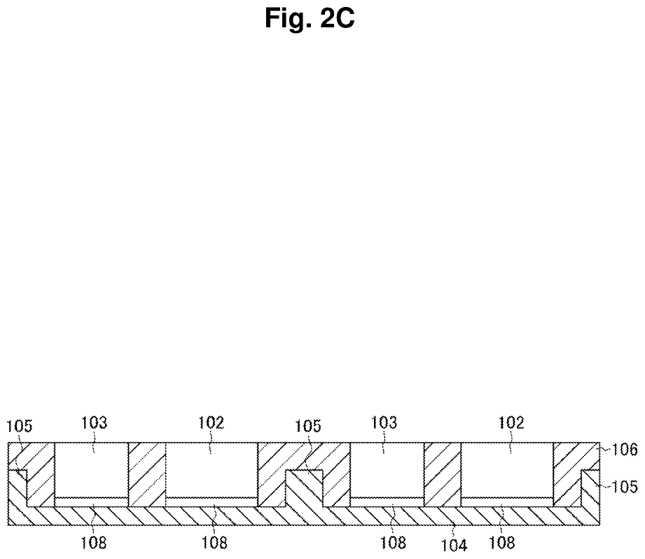

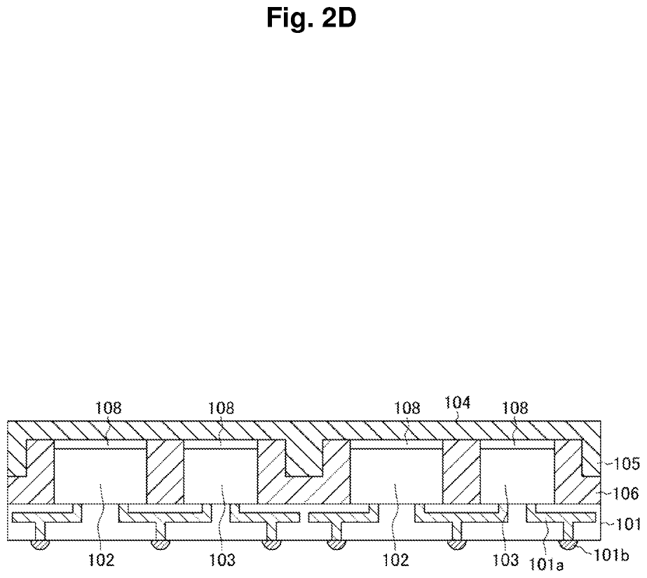

Next, a method for manufacturing a semiconductor device according to the present invention will be described with reference to FIGS. 2A to 2D.

First, as illustrated in FIG. 2A, the back surface of the first semiconductor chip 102 in which the first integrated circuit is formed on the main surface and the back surface of the second semiconductor chip 103 in which the second integrated circuit is formed on the main surface are fixed to the heat sink 104 (first step). As described above, the heat sink 104 includes a material having a thermal conductivity greater than thermal conductivities of the first semiconductor chip 102 and the second semiconductor chip 103. In addition, the reinforcing rib 105 is formed on the heat sink 104, and the first semiconductor chip 102 and the second semiconductor chip 103 are fixed to a region where the reinforcing rib 105 is not formed. For example, these are fixed by the adhesive layer 108 including solder or the like. The reinforcing rib 105 is formed on the wiring layer 101 side of the heat sink 104.

Next, as illustrated in FIG. 2B, the first semiconductor chip 102 and the second semiconductor chip 103 fixed to the heat sink 104 are molded with a molding resin on the heat sink 104 to form the molding resin layer 106 (second step). The molding resin layer 106 can be formed by, for example, forming a layer of the molding resin by a known compression molding method, transfer molding method, or the like and curing the layer of the molding resin formed.

Next, as illustrated in FIG. 2C, the molding resin layer 106 on the main surface side of each of the first semiconductor chip 102 and the second semiconductor chip 103 is thinned by grinding or the like to expose the main surfaces (integrated circuit formation surfaces) of the first semiconductor chip 102 and the second semiconductor chip 103. For example, the above-described thinning can be performed by a well-known grinding technology or the like.

Next, as illustrated in FIG. 2D, the wiring layer 101 including the wiring 101a is formed by, for example, a known build-up method (third step). In the case of assuming secondary mounting on a printed circuit board, the terminal 101b by a solder bump or the like is formed on the wiring layer 101. Through this step, the first semiconductor chip 102 and the second semiconductor chip 103 are disposed on the wiring layer 101. Formation to a state is performed in which the first integrated circuit and the second integrated circuit are connected to the wiring 101a, and the first semiconductor chip 102 and the second semiconductor chip 103 are molded with the molding resin layer 106 on the wiring layer 101. Note that, in this type of technology, the wiring layer 101 manufactured in this manner may be referred to as a rewiring layer.

Thereafter, the heat sink 104 is cut to be singulated into individual semiconductor devices (packages). For example, singulation can be performed by a known dicing technology. After the singulation, each semiconductor device is mounted on the printed circuit board as described with reference to FIG. 1. For example, in a case where the terminal 101b is a solder bump, the mounting on the printed circuit board can be performed by using a known reflow technology.

As described above, according to the embodiment, manufacturing is performed with the heat sink 104 as a support substrate, and after the wiring layer 101 is formed, singulation is performed without peeling off the heat sink 104 used as the support substrate, so that the manufacturing step is simplified, and the WLP structure capable of obtaining high heat dissipation can be manufactured while suppressing the manufacturing cost. In addition, as described above, since the reinforcing rib 105 is provided, even if the plate thickness of the heat sink 104 is made thinner in a state where high strength is maintained, it is possible to withstand a manufacturing process as the support substrate, and the WLP structure capable of obtaining high heat dissipation can be formed thinner.

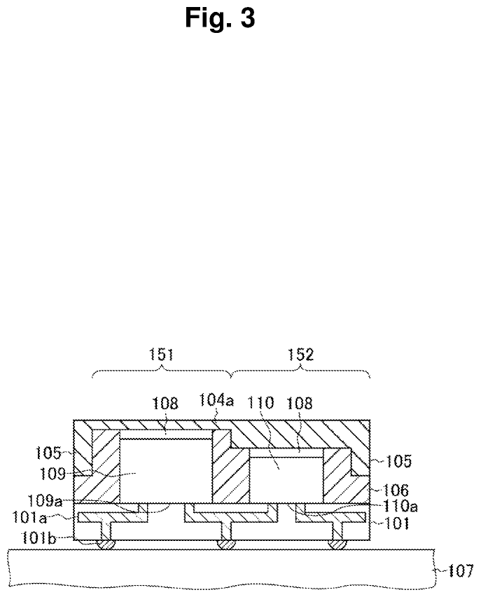

Meanwhile, as illustrated in FIG. 3, a first semiconductor chip 109 and a second semiconductor chip 110 having different thicknesses can also be used. For example, the first semiconductor chip 109 can be formed to be thicker than the second semiconductor chip 110. A first integrated circuit 109a electrically connected to the wiring 101a is formed on a main surface of the first semiconductor chip 109 facing the wiring layer 101 side. A second integrated circuit 110a electrically connected to the wiring 101a is formed on a main surface of the second semiconductor chip 110 facing the wiring layer 101 side. In this case, the plate thickness of a heat sink 104a in a second region 152 where the second semiconductor chip 110 is disposed is made thicker than the plate thickness of the heat sink 104 in a first region 151 where the first semiconductor chip 109 is disposed. The other configurations are similar to those described above.

In addition, in the method for manufacturing a semiconductor device in this case, in the above-described manufacturing method, the plate thickness of the heat sink 104 at a position where the second semiconductor chip 110 is disposed is made thicker than the plate thickness of the heat sink 104 at a position where the first semiconductor chip 109 is disposed.

As described above, according to the present invention, since the heat sink includes the reinforcing rib, it becomes possible to form a thinner WLP structure capable of obtaining high heat dissipation while the manufacturing cost is suppressed.

Note that it is obvious that the present invention is not limited to the embodiment described above, but can be modified and combined in many ways by a person having ordinary knowledge in the art within the technical idea of the present invention.

### REFERENCE SIGNS LIST

101 wiring layer
101a wiring
101b terminal
102 first semiconductor chip
102a first integrated circuit
103 second semiconductor chip
103a second integrated circuit
104 heat sink
105 reinforcing rib
106 molding resin layer
107 printed circuit board
108 adhesive layer

1. A semiconductor device comprising:
a wiring layer in which wiring is formed;
a first semiconductor chip and a second semiconductor chip disposed on the wiring layer and molded with a molding resin layer including a molding resin;
a first integrated circuit formed on the first semiconductor chip and connected to the wiring;
a second integrated circuit formed on the second semiconductor chip and connected to the wiring;
a heat sink that is disposed on a back surface side of the first semiconductor chip and a back surface side of the second semiconductor chip, includes a material having a thermal conductivity greater than thermal conductivities of the first semiconductor chip and the second semiconductor chip, and dissipates heat of the first semiconductor chip and the second semiconductor chip; and
a reinforcing rib formed on the heat sink in a region where the first semiconductor chip and the second semiconductor chip are not disposed.

2. The semiconductor device according to claim 1, wherein
the reinforcing rib is formed on the wiring layer's side of the heat sink.

3. The semiconductor device according to claim 1, wherein
the first semiconductor chip is formed to be thicker than the second semiconductor chip, and
a plate thickness of the heat sink on which the second semiconductor chip is disposed is made thicker than a plate thickness of the heat sink on which the first semiconductor chip is disposed.

4. A method for manufacturing a semiconductor device, comprising:
a first step of fixing a back surface of a first semiconductor chip in which a first integrated circuit is formed on a main surface and a back surface of a second semiconductor chip in which a second integrated circuit is formed on a main surface, to a region where a reinforcing rib is not formed, of a heat sink on which the reinforcing rib is formed and that includes a material having a thermal conductivity greater than thermal conductivities of the first semiconductor chip and the second semiconductor chip;
a second step of molding the first semiconductor chip and the second semiconductor chip fixed to the heat sink with a molding resin on the heat sink to form a molding resin layer; and
a third step of performing formation to a state in which the first semiconductor chip and the second semiconductor chip are disposed on a wiring layer including wiring, the first integrated circuit and the second integrated circuit are connected to the wiring, and the first semiconductor chip and the second semiconductor chip are molded with the molding resin layer on the wiring layer.

5. The method for manufacturing a semiconductor device according to claim 4, wherein
the reinforcing rib is formed on the wiring layer's side of the heat sink.

6. The method for manufacturing a semiconductor device according to claim 4, wherein
the first semiconductor chip is formed to be thicker than the second semiconductor chip, and
a plate thickness of the heat sink on which the second semiconductor chip is disposed is made thicker than a plate thickness of the heat sink on which the first semiconductor chip is disposed.

7. The semiconductor device according to claim 2, wherein
the first semiconductor chip is formed to be thicker than the second semiconductor chip, and
a plate thickness of the heat sink on which the second semiconductor chip is disposed is made thicker than a plate thickness of the heat sink on which the first semiconductor chip is disposed.

8. The method for manufacturing a semiconductor device according to claim 5, wherein
the first semiconductor chip is formed to be thicker than the second semiconductor chip, and
a plate thickness of the heat sink on which the second semiconductor chip is disposed is made thicker than a plate thickness of the heat sink on which the first semiconductor chip is disposed.
